(19) United States
(12) Patent Application Publication
(10) Pub. No.: US 2013/0074923 A1
(43) Pub. Date: Mar. 28, 2013

(54) METHOD FOR PRODUCING ZINC-OXIDE NANOSTRUCTURE ELECTRODES, AND METHOD FOR PRODUCING DYE-SENSITIZED SOLAR CELLS USING SAME

(71) Applicants: Gun-Young Jung, Buk-gu (KR); Ki-Seok Kim, Buk-gu (KR); Jin-Ju Kim, Buk-gu (KR)

(72) Inventors: Gun-Young Jung, Buk-gu (KR); Ki-Seok Kim, Buk-gu (KR); Jin-Ju Kim, Buk-gu (KR)

(73) Assignee: GWANGJU INSTITUTE OF SCIENCE AND TECHNOLOGY, Buk-gu, Gwangju (KR)

(21) Appl. No.: 13/701,714

(22) PCT Filed: Jul. 13, 2011
(86) PCT No.: PCT/KR2011/005166

§ 371 Date: Dec. 3, 2012

(30) Foreign Application Priority Data
Jul. 16, 2010 (KR) 10-2010-0068973

(51) Int. Cl. H01L 31/18; H01L 31/0224

(52) U.S. Cl. CPC H01L 31/1884; H01L 31/022483; Y10S 977/948; B82Y 99/00
USPC 136/256; 438/98; 977/948

(57) ABSTRACT

Provided are a method of preparing a zinc oxide nanostructure electrode and a method of preparing a dye-sensitized solar cell using the same. According to the present invention, the method of preparing a zinc oxide nanostructure electrode may include sequentially forming a superhydrophobic self-assembled layer and a zinc layer on a carrier substrate having a stamp pattern included therein, disposing the zinc layer on the carrier to face a first substrate and performing a stamp method to form at least one zinc pattern on the first substrate, oxidizing the zinc pattern to form zinc oxide seeds, and growing at least one zinc oxide nanostructure from the zinc oxide seeds by using a hydrothermal synthesis method to form a zinc oxide nanostructure electrode composed of the at least one zinc oxide nanostructure.

### CROSS-REFERENCE TO RELATED APPLICATION

This application claims priority to Korean Patent Application No. 10-2010-0068973 filed on 16 Jul., 2010 and all the benefits accruing therefrom under 35 U.S.C. §119, the contents of which are incorporated by reference in their entirety.

### TECHNICAL FIELD

The present invention disclosed herein relates to a method of preparing a zinc oxide nanostructure electrode and a method of preparing a dye-sensitized solar cell using the same.

### BACKGROUND ART

Recently, a wide range of research into utilizing natural energies, such as wind power, nuclear power, and solar power, as energy sources able to substitute typical fossil fuel has been conducted in order to address current energy issues.

Solar cells using solar energy among the natural energies, differing from the other energy sources, have unlimited resource and are environmentally friendly.

With respect to solar cells, silicon-based solar cells have been currently developed and are in a commercialization stage. However, the silicon-based solar cells may have a complicated manufacturing process and may have high manufacturing costs.

In order to overcome such limitations, interests in dye-sensitized solar cells having low manufacturing costs and a relatively simple manufacturing process are increased.

The dye-sensitized solar cells, differing from the silicon-based solar cells, are photoelectrochemcial solar cells mainly composed of a dye absorbing visible light to form electron-hole pairs and transition metal oxide transferring the generated electrons. Among typical dye-sensitized solar cells, a representative research and development may include a dye-sensitized solar cell using titanium oxide (anatase) nanoparticles developed by a Michael Gratzel's research team at Ecole Polytechnique de Federale de Lausanne (EPFL) in 1991.

This dye-sensitized solar cell may have advantages in that manufacturing costs thereof may be low and applications in building's exterior windows and glass greenhouse may be possible due to a transparent electrode, but may have limitations in practical use due to a low photoelectric conversion efficiency.

Since the photoelectric conversion efficiency of a solar cell is proportional to an amount of electrons generated by the absorption of sunlight, there may be a method of increasing the amount of generated electrons by increasing the absorption of sunlight or an amount of the adsorbed dye, or a method of preventing annihilation of the generated excited electrons by recombination of the electron-hole pairs in order to increase the efficiency.

A method of decreasing particles of oxide semiconductor to a nanometer-scale size in order to increase the amount of the adsorbed dye per unit area, or a method of increasing reflectance of a platinum electrode or mixing semiconductor oxide light scatterers having a few micrometer size in order to increase the absorption of sunlight has been developed. However, there may be limitations in improving the photoelectric conversion efficiency of a solar cell by using these typical methods. Therefore, there is an urgent need to develop a new technique for improving the efficiency.

### DISCLOSURE

### Technical Problem

The present invention provides a method of preparing a vertically-grown, well-aligned, and patterned zinc oxide nanostructure electrode.

The present invention also provides a method of preparing a zinc oxide nanostructure electrode at a low temperature.

The present invention also provides a method of preparing a zinc oxide nanostructure electrode, in which a substrate is not damaged by using a non-aqueous process and not using processes employing an aqueous solution, such as an etching process, a photolithography process, and a lift-off process.

The present invention also provides a method of preparing a zinc oxide nanostructure electrode on a flexible substrate.

The present invention also provides a method of preparing a dye-sensitized solar cell including the methods of preparing a zinc oxide nanostructure electrode.

### Technical Solution

In accordance with an exemplary embodiment of the present invention, a method of preparing a zinc oxide nanostructure electrode includes: sequentially forming a superhydrophobic self-assembled layer and a zinc layer on a carrier substrate having a stamp pattern included therein; disposing the zinc layer on the carrier to face a first substrate and performing a stamp method to form at least one zinc pattern on the first substrate; oxidizing the zinc pattern to form zinc oxide seeds; and growing at least one zinc oxide nanostructure from the zinc oxide seeds by using a hydrothermal synthesis method to form a zinc oxide nanostructure electrode composed of the at least one zinc oxide nanostructure.

The first substrate may include a transparent flexible substrate and a transparent conductive layer disposed on a surface of the flexible substrate, and the zinc pattern may be disposed on the transparent conductive layer.

The transparent flexible substrate may be any one of an ultra-thin glass substrate, a polyethylene terephthalate (PET) substrate, a polycarbonate (PC) substrate, a polyether sulfone (PES) substrate, a polyimide (PI) substrate, a polynorbonene substrate, and a polyethylene naphthalate (PEN) substrate.

The oxidizing of the zinc pattern to form zinc oxide seeds may include oxidizing the zinc pattern by dipping the first substrate having the zinc pattern formed thereon in a polar solution as a hydroxide ion source to form the zinc oxide seeds.

The polar solution as a hydroxide ion source may include any one of NH₄OH, KOH, LiOH, and NaOH.

The growing of the at least one zinc oxide nanostructure from the zinc oxide seeds by using a hydrothermal synthesis method to form a zinc oxide nanostructure electrode composed of the at least one zinc oxide nanostructure may be performed by dipping the first substrate having the zinc oxide seeds formed thereon in a hydrothermal solution, and the hydrothermal solution may include water, a zinc ion source supplying zinc ions by reacting with the water, and a hydroxide ion source supplying hydroxide ions by reacting with the water.

The zinc ion source may be any one of zinc acetate (Zn(O₂CCH₃)₂), zinc nitrate (Zn(NO₃)₂), zinc sulfate (ZnSO₄), and zinc chloride (ZnCl₂).

The hydroxide ion source may be hexamethylenetetramine

In accordance with another exemplary embodiment of the present invention, a method of preparing a dye-sensitized solar cell includes: sequentially forming a superhydrophobic self-assembled layer and a zinc layer on a carrier substrate having a stamp pattern included therein; disposing the zinc layer on the carrier to face a first substrate and performing a stamp method to form at least one zinc pattern on the first substrate; oxidizing the zinc pattern to form zinc oxide seeds; growing at least one zinc oxide nanostructure from the zinc oxide seeds by using a hydrothermal synthesis method to form a zinc oxide nanostructure electrode composed of the at least one zinc oxide nanostructure; adsorbing a dye on the zinc oxide nanostructure electrode; and sealing by fastening the first substrate having the dye adsorbed thereon and a second substrate to fill an electrolyte therebetween.

The second substrate may further include a platinum (Pt) layer on a surface facing the first substrate.

The second substrate may include a transparent flexible substrate and a transparent conductive layer disposed on a surface of the flexible substrate, and the Pt layer may be disposed on the transparent conductive layer.

The second substrate may be a conductive flexible substrate.

The sealing by fastening the first substrate and the second substrate may include sealing by fastening an edge of the first substrate and an edge of the second substrate with a fastening member, and the first substrate and the second substrate may be spaced apart with a predetermined spacing and fastened.

In accordance with another exemplary embodiment of the present invention, a dye-sensitized solar cell includes: a first substrate; and at least one patterned zinc oxide nanostructure electrode disposed on the first substrate and composed of at least one zinc oxide nanostructure.

The dye-sensitized solar cell may further include: a dye adsorbed on a surface of the zinc oxide nanostructure of the zinc oxide nanostructure electrode; a second substrate facing the first substrate; a fastening member fastening and sealing the first substrate and the second substrate; and an electrolyte filled between the first substrate and the second substrate.

The first substrate may include a transparent flexible substrate and the second substrate may include a flexible substrate.

### Advantageous Effects

According to the constitution of the present invention, purpose of the present invention previously described may be entirely achieved. Specifically, according to the present invention, a method of preparing a vertically-grown, well-aligned, and patterned zinc oxide nanostructure electrode may be provided.

Also, according to the present invention, since a separate etching process and a lift-off process may not be required for a substrate having a nanostructure grown thereon and a zinc oxide nanostructure may be formed at a low temperature, a zinc oxide nanostructure electrode may be easily prepared on a flexible substrate easily subjected to thermal or chemical damage.

According to the present invention, a method of preparing a dye-sensitized solar cell including the method of preparing a zinc oxide nanostructure electrode may be provided.

Further, according to the present invention, a method of preparing a flexible dye-sensitized solar cell having a high photoelectric conversion efficiency may be provided.

### DESCRIPTION OF DRAWINGS

FIGS. 1 through 6 are sectional views illustrating a method of preparing a zinc oxide nanostructure electrode according to an embodiment of the present invention;

FIGS. 7 and 8 are sectional views illustrating a method of preparing a dye-sensitized solar cell according to an embodiment of the present invention;

FIG. 9A is a micrograph showing a zinc oxide nanostructure electrode well aligned and patterned by the method of preparing a zinc oxide nanostructure electrode according to the embodiment of the present invention, FIG. 9B is a micrograph showing an unpatterned zinc oxide nanostructure electrode, and FIGS. 9C and 9D are graphs showing the results of transmittance and absorption measurements for the patterned zinc oxide nanostructure electrode of the present invention and the unpatterned zinc oxide nanostructure electrode;

FIG. 10 is a sectional view illustrating a dye-sensitized solar cell prepared by using the method of preparing a dye-sensitized solar cell according to the embodiment of the present invention after bending; and

FIG. 11 is an actual photograph showing an image of measuring the performance of the dye-sensitized solar cell prepared by using the method of preparing a dye-sensitized solar cell according to the embodiment of the present invention after bending.

### BEST MODE

Hereinafter, preferred embodiments of the present invention will be described in detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout.

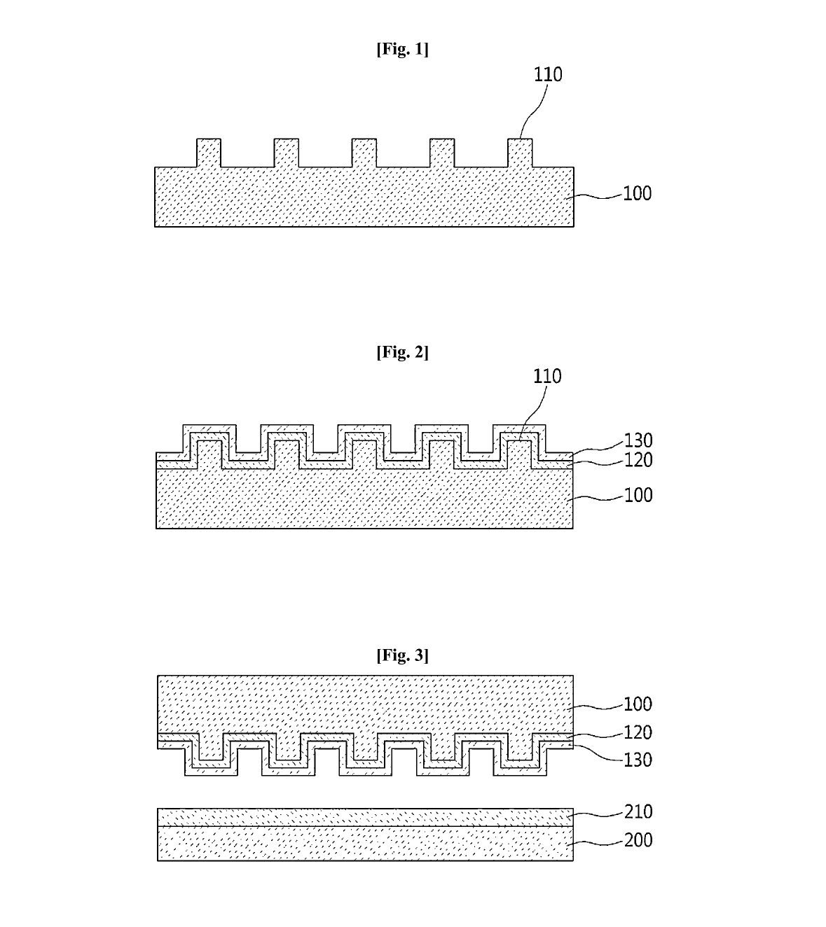

FIGS. 1 through 6 are sectional views illustrating a method of preparing a zinc oxide nanostructure electrode according to an embodiment of the present invention.

Referring to FIGS. 1 through 6, in the method of preparing a zinc oxide nanostructure electrode according to the embodiment of the present invention, a carrier substrate 100 including at least one stamp pattern 110, for example, the plurality of stamp patterns 110, is first prepared as illustrated in FIG. 1.

The carrier substrate 100 may be formed of any material so long as the material may form the stamp pattern 110. The carrier substrate 100 may be formed of glass, silicon, metal, or a polymer.

The stamp patterns 110 may be included on a surface of one side of the carrier substrate 100. The stamp patterns 110 may be formed in an appropriate size in consideration of sizes of zinc patterns 132 or zinc oxide seeds 220 to be described later.

The stamp pattern 110 may be a circular pattern or a polygonal pattern including a triangular or rectangular pattern and may be a three-dimensional cylinder pattern having various shapes, such as a circular cylinder and a polygonal cylinder including a triangular cylinder or a rectangular cylinder.

The stamp patterns 110 may be included to maintain an appropriate spacing in order for zinc oxide nanostructure electrodes 230 formed on a first substrate 200 to be later described not to be broken by bumping into each other during bending of the first substrate 200.

The stamp patterns 110 may be included by regularly being disposed and patterned on the surface of one side of the carrier substrate 100.

The stamp patterns 110 may be formed on the surface of one side of the carrier substrate 100 by using various methods. For example, a lithography method, such as an X-ray lithography method, an extreme ultraviolet lithography method, a nanolithography method, or an electron beam lithography method, may be used or a laser interference lithography (LIL) method using a laser beam may be used.

Continuously, as illustrated in FIG. 2, a superhydrophobic self-assembled layer 120 and a zinc layer 130 are sequentially formed on the surface of one side of the carrier substrate 100.

The superhydrophobic self-assembled layer 120 acts to decrease bonding force between the carrier substrate 100 and the zinc layer 130 by controlling surface energy of the surface of one side of the carrier substrate 100.

The superhydrophobic self-assembled layer 120 may be formed of a fluorine-based material and may be formed by including tridecafluoro-1,1,2,2-tetrahydrooctyltrichlorosilane (CF₃(CF₂)₅(CH₂)₂SiCl₃). The superhydrophobic self-assembled layer 120 may be formed by using a vapor-phase deposition method or a dipping method.

The zinc layer 130 may be formed by using a physical vapor deposition method or a chemical vapor deposition method.

Continuously, as illustrated in FIG. 3, the surface of one side of the carrier substrate 100 having the superhydrophobic self-assembled layer 120 and the zinc layer 130 formed thereon is disposed to face a surface of one side of the first substrate 200.

Any substrate used in semiconductor devices, displays, or solar cells, for example, a substrate formed of oxide, such as a glass substrate or sapphire substrate, a substrate formed of a semiconductor material, such as a silicon substrate or a GaAs substrate, a substrate formed of a conductive material, such as a metal substrate or metal foil substrate, or a substrate formed of a polymer, such as a plastic substrate, may be used as the first substrate 200. Also, a rigid substrate or a flexible substrate may be used as the first substrate 200.

The first substrate 200 may be a transparent substrate. For example, the first substrate may be a transparent flexible substrate and the transparent flexible substrate may be an ultra-thin glass substrate or a plastic substrate.

At this time, the ultra-thin glass not only denotes a glass substrate used in typical displays or solar cells, but also denotes a flexible glass substrate having a thickness ranging from 50 μm to 100 μm.

Examples of the plastic substrate may be a polyethylene terephthalate (PET) substrate, a polycarbonate (PC) substrate, a polyether sulfone (PES) substrate, a polyimide (PI) substrate, a polynorbonene substrate, and a polyethylene naphthalate (PEN) substrate. Therefore, any one of the ultra-thin glass substrate, the PET substrate, the PC substrate, the PES substrate, the PI substrate, the polynorbonene substrate, and the PEN substrate may be used as the first substrate 200.

At this time, a transparent conductive layer 210 may be positioned on the surface of one side of the first substrate 200.

The transparent conductive layer 210 acts to electrically connect between the zinc oxide nanostructure electrodes 230 to be later described to connect them to other external apparatuses or devices. The transparent conductive layer 210 may be formed of a transparent conductive material and for example, may be transparent conductive oxide such as indium tin oxide (ITO). Also, the transparent conductive layer 210 may be formed of a transparent conductive material such as carbon nanotubes. However, since the zinc oxide nanostructure electrode 210 according to the embodiment of the present invention may be used in a dye-sensitized solar cell, a material of the transparent conductive layer 210 may be appropriately selected in consideration of a work function with respect to another electrode corresponding to the zinc oxide nanostructure electrode 210, i.e., a counter electrode 320 to be described later.

Meanwhile, a process of respectively cleaning the surface of one side of the carrier substrate 100 and the surface of one side of the first substrate 200 by using ethanol or ultrapure water may be further performed before the surface of one side of the carrier substrate 100 and the surface of one side of the first substrate 200 are disposed to face each other.

Continuously, as illustrated in FIG. 4, a stamp method is performed to form at least one zinc pattern 132 on the surface of one side of the first substrate 200. The stamp method may be performed to form the plurality of zinc patterns 132 to be well-aligned and patterned on the surface of one side of the first substrate 200.

At this time, the stamp method is a method in which a predetermined pressure is applied to a surface of the other side of the first substrate 200 to transfer a portion of the zinc layer 130 on the surface of one side of the first substrate 200, precisely the zinc layer 130 disposed on the stamp patterns 110 of the first substrate 200, to the surface of one side of the first substrate 200, for example, the transparent conductive layer 210.

In the case that the first substrate 200 is a plastic substrate, the stamp method is performed at a glass transition temperature or less, for example, at 100° C., in order for the first substrate 200 not to be deformed by heat, and the pressure may be applied to the first substrate 200 at an appropriate pressure able to form the stamp patterns 110 on the first substrate 200, for example, 100 bars, for an appropriate period of time, for example, about 20 minutes.

Continuously, the zinc patterns 132 formed on the first substrate 200 are oxidized to form zinc oxide seeds 220 on the first substrate 200 as illustrated in FIG. 5.

A method of forming the zinc oxide seeds 220 may be performed by dipping the first substrate 200 having the zinc patterns 132 formed thereon in a polar solution as a hydroxide ion source. The polar solution as a hydroxide ion source may include any one of NH₄OH, KOH, LiOH, and NaOH, which provide hydroxide ions. The zinc patterns 132 are oxidized by oxygen supplied from hydroxide ions (OH⁻) in the polar solution as a hydroxide ion source to be formed as the zinc oxide seeds 220.

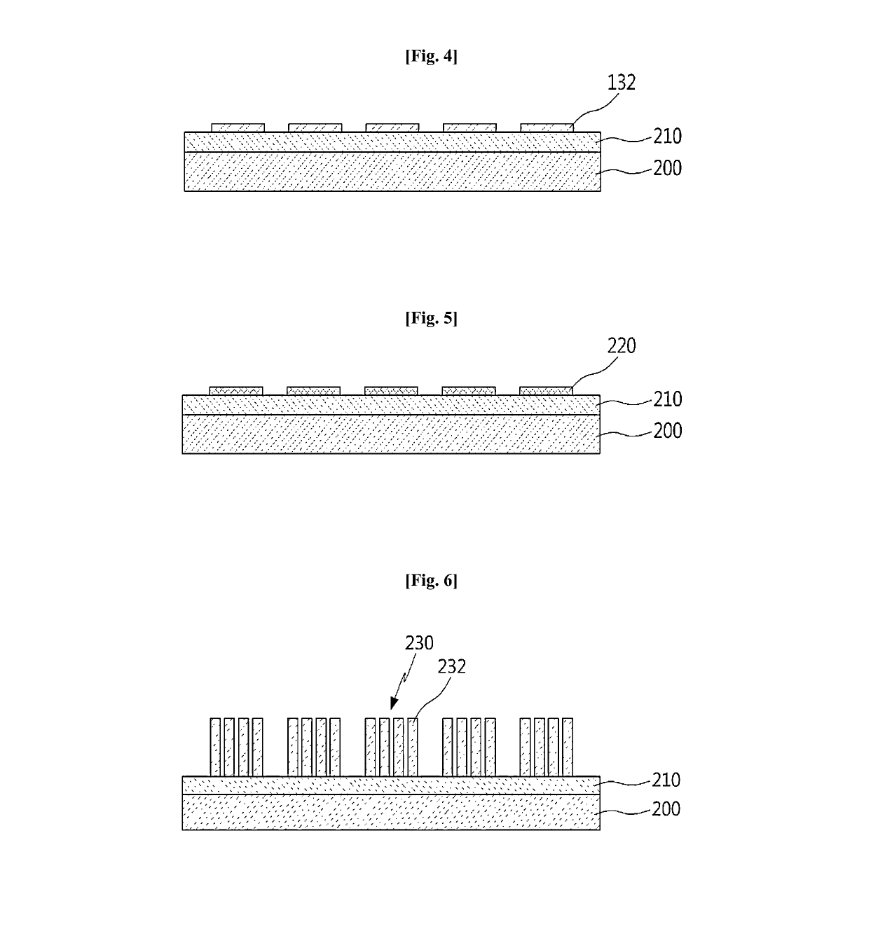

Thereafter, a zinc oxide nanostructure 232 is grown from the zinc oxide seed 220 by using a hydrothermal synthesis method to form a zinc oxide nanostructure electrode 230 composed of the zinc oxide nanostructure 232 as illustrated in FIG. 6. The zinc oxide nanostructure electrode 230 may be formed by vertically growing at least one zinc oxide nanostructure 232, for example, the plurality of zinc oxide nanostructures 232. Since the zinc oxide nanostructure electrode 230 is formed by growing from the zinc oxide seeds 220 well-aligned and patterned on the first substrate 200, the zinc oxide nanostructure electrode 230 is composed of at least one vertically grown zinc oxide nanostructure 232. Therefore, the zinc oxide nanostructure electrodes 230 may be formed by being regularly aligned and patterned according to the arrangement of the zinc oxide seeds 220.

The forming of the zinc oxide nanostructure electrode 230 by the hydrothermal synthesis method may be performed by dipping the first substrate 200 having the zinc oxide seeds 220 formed thereon in a hydrothermal solution.

The hydrothermal solution may include water, a zinc ion source supplying zinc ions by reacting with the water, and a hydroxide ion source supplying hydroxide ions by reacting with the water.

At this time, the zinc ion source may be any one of zinc acetate (Zn(O₂CCH₃)₂), zinc nitrate (Zn(NO₃)₂), zinc sulfate (ZnSO₄), and zinc chloride (ZnCl₂), and the hydroxide ion source may be hexamethylenetetramine.

Therefore, the method of preparing a zinc oxide nanostructure electrode according to the embodiment of the present invention may provide a method of preparing the zinc oxide nanostructure electrodes 230 on the transparent and flexible first substrate 200 by using a stamp method, an oxidation method using a polar solution as a hydroxide ion source and a hydrothermal synthesis method.

Since the method of preparing a zinc oxide nanostructure electrode is performed at a low temperature, a preparation method which does not damage the transparent and flexible first substrate 200 may be provided.

Also, in the method of preparing a zinc oxide nanostructure electrode, a process of using an aqueous solution, such as an etching process including dry etching and wet etching, a photolithography process, and a lift-off process, is not used, but a non-aqueous process is used, and thus, a preparation method which does not chemically damage the transparent and flexible first substrate 200 may be provided.

Since the method of preparing a zinc oxide nanostructure electrode provides a method of preparing the zinc oxide nanostructure electrode 230 composed of at least one zinc oxide nanostructure 232, for example, the plurality of zinc oxide nanostructures 232, a method of preparing the zinc oxide nanostructure electrodes 230 having a high surface area may be provided.

Further, since the method of preparing a zinc oxide nanostructure electrode provides a method of preparing the zinc oxide nanostructure electrodes 230 regularly aligned and patterned by growing from the zinc oxide seeds 220 derived from the zinc patterns 132 regularly aligned by using a stamp method, a method of preparing the zinc oxide nanostructure electrodes 230 may be provided, in which the method allows the zinc oxide nanostructure electrodes 230 not to be damaged by bumping into each other even in the case that the first substrate 200 is bent.

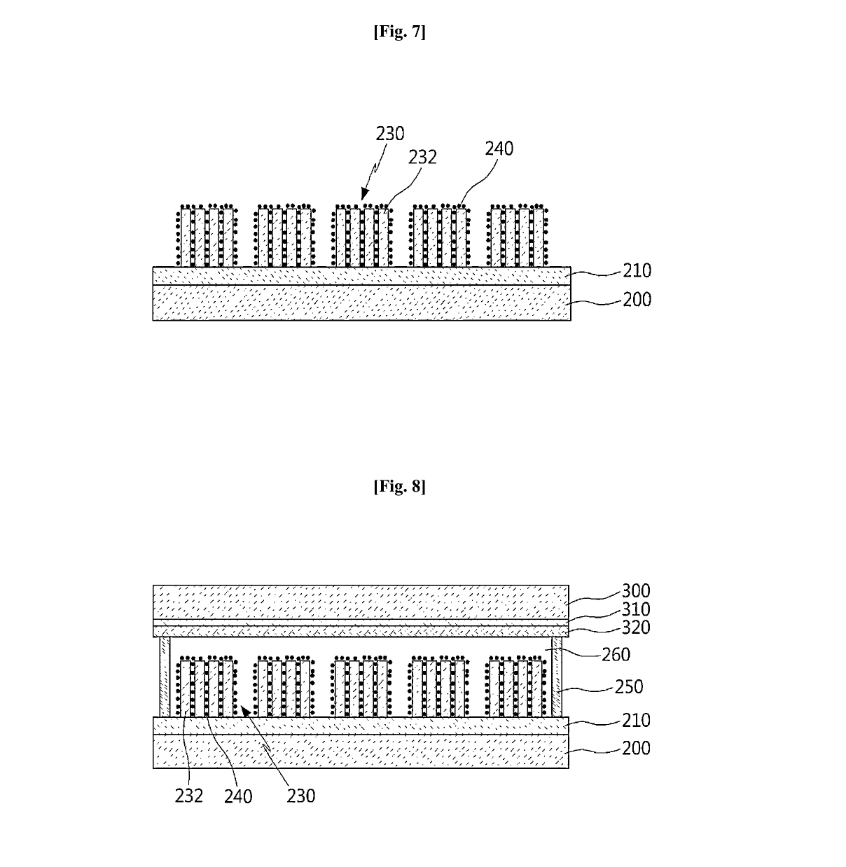

FIGS. 7 and 8 are sectional views illustrating a method of preparing a dye-sensitized solar cell according to an embodiment of the present invention.

Referring to FIGS. 7 and 8, in the method of preparing a dye-sensitized solar cell according to the embodiment of the present invention, a first substrate 200 having zinc oxide nanostructure electrodes 230 formed thereon prepared according to the method of preparing a zinc oxide nanostructure electrode according to the embodiment of the present invention described with reference to FIGS. 1 through 6 is first prepared.

Continuously, adsorption of a dye on the zinc oxide nanostructure electrodes 230 is performed to allow a dye 240 to be adsorbed on the zinc oxide nanostructure electrodes, precisely surfaces of the zinc oxide nanostructures 232 of the zinc oxide nanostructure electrodes 230 as illustrated in FIG. 7.

A dye generating electron-hole pairs by absorbing light, for example, a ruthenium-based dye, a polymer dye, or a dye utilizing quantum dots, may be used as the dye 240. At this time, the ruthenium-based dye may be Ru[dcbpy(TBA)₂]₂(NCS)₂, the polymer dye may be a P3HT-PCBM coating polymer, and CdSe or ZnSe may be used as the quantum dots.

A process of adsorbing the dye 240 on the zinc oxide nanostructure electrodes 230 may be performed at a temperature of 100° C. or less, for example, 60° C., for about 2 hours or may be performed at room temperature for about 24 hours.

Thereafter, the first substrate 200 having the dye 240 adsorbed thereon and a second substrate 300 are fastened by using fastening members 250 and sealed as illustrated in FIG. 8, in which the fastening is performed to fill an electrolyte 260 between the first substrate 200 and the second substrate 300 and thus, a dye-sensitized solar cell is formed.

The fastening member 250 acts to fasten and simultaneously seal the first substrate 200 and the second substrate 300. The fastening member 250 also acts as a spacer that maintains a predetermined spacing between the first substrate 200 and the second substrate 300.

The fastening member 250 may be a double sided tape and may be an organic material having adhesiveness.

A thickness of the fastening member 250 may be in a range of 3 μm to 6 μm, for example, 4.5 μm, and as a result, the spacing between the first substrate 200 and the second substrate 300 may be maintained in a range of 3 μm to 6 μm.

The fastening member 250 is disposed at an edge of the first substrate 200 and an edge of the second substrate 300, and may be included by fastening the first substrate 200 and the second substrate 300.

At this time, the same substrate as the first substrate 200 may be used as the second substrate 300. Also, a flexible substrate including a metal foil may be used as the second substrate 300. That is, all flexible substrates regardless of the presence of transparency may be used as the second substrate 300.

A transparent conductive layer 310 and a counter electrode 320 disposed on the transparent conductive layer 310 are included on a surface of one side of the second substrate 300, for example, a surface facing the surface of one side of the first substrate 200.

At this time, the transparent conductive layer 310 may be formed of a transparent conductive material as that of the transparent conductive layer 210 on the first substrate 200. Meanwhile, in the case that the second substrate 300 is formed of a conductive material such as a metal foil, the transparent conductive layer 310 may be omitted.

The counter electrode 320 may be formed of a platinum (Pt) layer in consideration of a work function of the electrode on the first substrate 200 as in the case of the zinc oxide nanostructure electrode 230.

Any electrolyte used in a dye-sensitized solar cell may be used as the electrolyte 260. For example, 1-hexyl-2,3-dimethyl imidazolium iodide may be used as the electrolyte 260.

The first substrate 200 and the second substrate 300 are fastened with the fastening members 250 and the electrolyte 260 may then be injected into a space between the first substrate 200 and the second substrate 300.

### Experimental Example 1

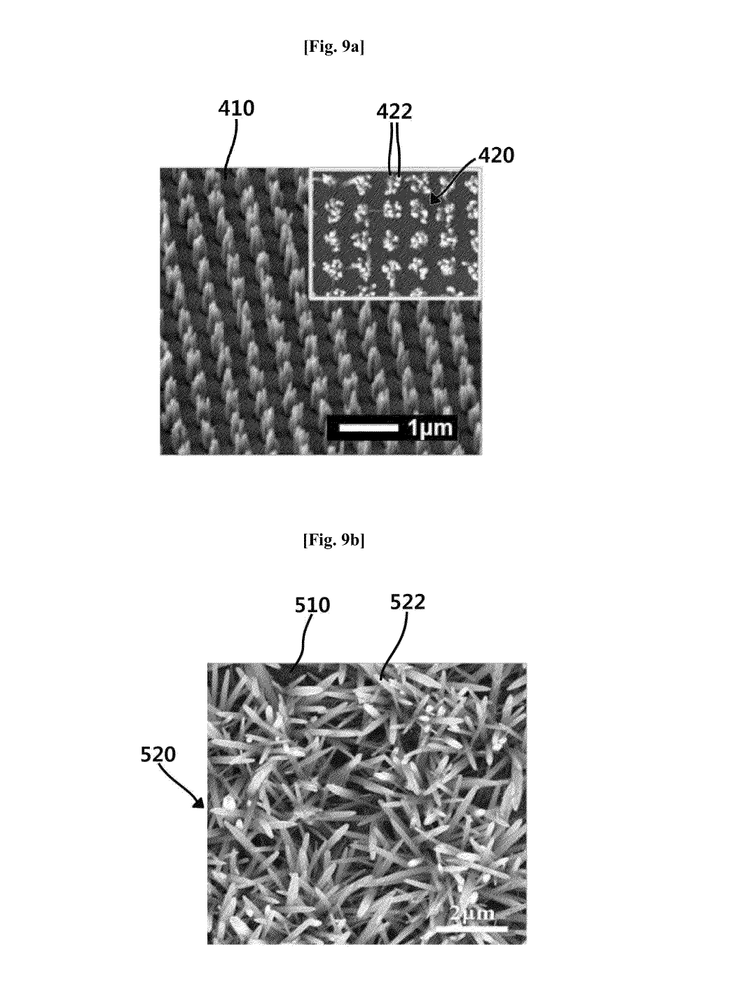

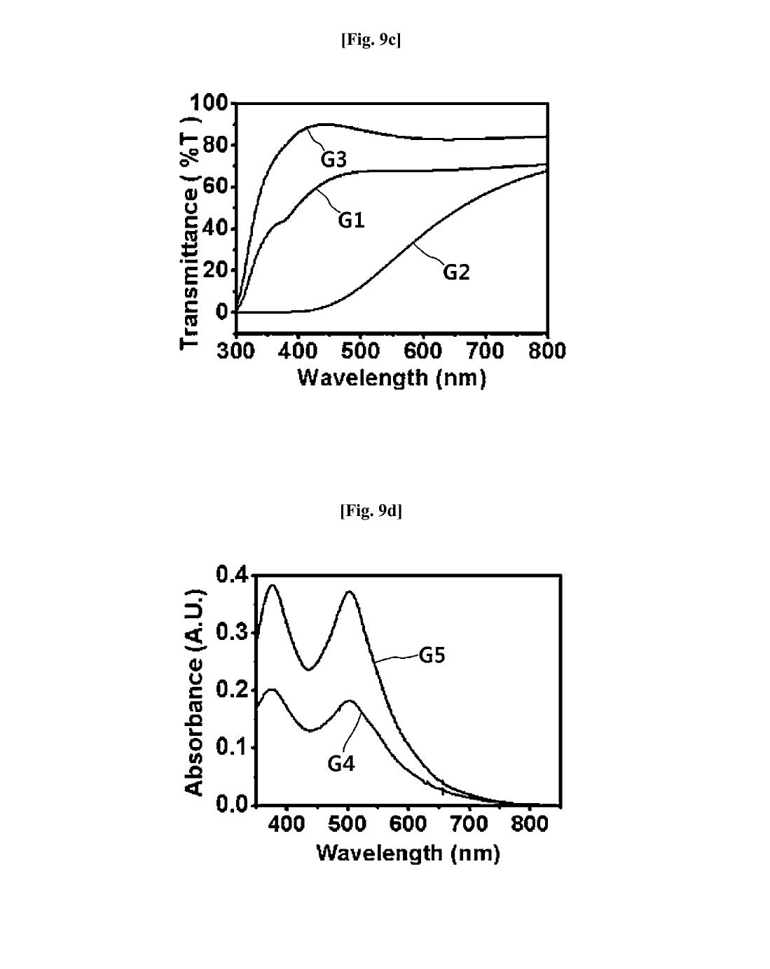

FIG. 9A is a micrograph showing a zinc oxide nanostructure electrode well aligned and patterned by the method of preparing a zinc oxide nanostructure electrode according to the embodiment of the present invention, FIG. 9B is a micrograph showing an unpatterned zinc oxide nanostructure electrode, and FIGS. 9C and 9D are graphs showing the results of transmittance and absorbance measurements for the patterned zinc oxide nanostructure electrode of the present invention and the unpatterned zinc oxide nanostructure electrode.

Referring to FIGS. 9A through 9D, the micrograph illustrated in FIG. 9A shows patterned zinc oxide nanostructure electrodes 420 (hereinafter, referred to as “zinc oxide nanostructure electrode 420 of the present invention”) composed of vertically well-aligned zinc oxide nanostructures 422 prepared on a substrate 410 according to the method of preparing a zinc oxide nanostructure electrode described with reference to FIGS. 1 to 6.

At this time, the substrate 410 was a PET substrate and an ITO layer was formed on the PET substrate as a transparent conductive layer. The superhydrophobic self-assembled layer 120 was tridecafluoro-1,1,2,2-tetrahydrooctyltrichlorosilane (CF₃(CF₂)₅(CH₂)₂SiCl₃) and the stamp method was performed at 100° C. by pressurizing at a pressure of 100 bars for 20 minutes.

A method of forming the zinc patterns 132 from the zinc oxide seeds 220 was performed by using a method of dipping in a polar solution as a hydroxide ion source including NH₄OH for 2 minutes. The hydrothermal synthesis method was performed at 80° C. for 4 hours by using a hydrothermal solution including water, zinc acetate, and hexamethylenetetramine.

In the micrograph illustrated in FIG. 9B, zinc oxide nanostructures 522 were formed on a substrate 510 by using a typical method of preparing a zinc oxide nanostructure (for example, a method of preparing a zinc oxide nanostructure by spin coating zinc nanoparticles or a method of preparing a zinc oxide nanostructure by depositing zinc oxide). Since the zinc oxide nanostructures 522 were poorly aligned and also not patterned as in the present invention, the plurality of zinc oxide nanostructures 522 disorderly formed on the substrate 510, i.e., formation of a poorly aligned and unpatterned zinc oxide nanostructure electrode 520 (hereinafter, referred to as “typical zinc oxide nanostructure electrode 520”), was shown.

The graph illustrated in FIG. 9C presents transmittances of the zinc oxide nanostructure electrode 420 of the present invention and the typical zinc oxide nanostructure electrode 520 formed on each substrate. According to the graph illustrated in FIG. 9C, it may be understood that the transmittance (G1) of the zinc oxide nanostructure electrode 420 of the present invention is higher than the transmittance (G2) of the typical zinc oxide nanostructure electrode 520 over the entire measured wavelength range including a visible light range (about 380 nm to 760 nm) of sunlight.

Also, since difference between two transmittances was not large when the transmittance (G1) of the zinc oxide nanostructure electrode 420 of the present invention and the transmittance (G3) of the substrate 410 itself (at this time, the substrate 410 was formed of a PET substrate and an ITO layer was formed on the PET substrate) were compared, it may be analyzed that the transmittance of the zinc oxide nanostructure electrode 420 of the present invention itself was considerably high. That is, the difference between two transmittances (i.e., G3−G1) may be considered as a degree of transmission of light prevented by the zinc oxide nanostructure electrode 420 of the present invention. However, since the difference between two transmittances was small, it may be analyzed that the transmittance of the zinc oxide nanostructure electrode 420 of the present invention was high.

The graph illustrated in FIG. 9D presents absorbances of the zinc oxide nanostructure electrode 420 of the present invention and the typical zinc oxide nanostructure electrode 520 after the adsorption of a dye, and it may be understood that the absorbance (G4) of the zinc oxide nanostructure electrode 420 of the present invention was lower that the absorbance (G5) of the typical zinc oxide nanostructure electrode 520. The reason for this is that since the zinc oxide nanostructure electrode 420 of the present invention was vertically well-aligned and patterned, an overall surface area thereof was relatively small in comparison to that of the typical zinc oxide nanostructure electrode 520, and thus, an amount of the adsorbed dye was relatively small.

However, in the case that the aligned zinc oxide nanostructure electrode 420 of the present invention and the typical disorderly grown zinc oxide nanostructure electrode 520 were used in a solar cell, a difference in efficiency according to the formed electrode was observed instead of changes in the efficiency according to the amount of the dye. In the case of the disorderly grown zinc oxide nanostructure electrode, low efficiency was obtained even though the amount of the adsorbed dye was high, according to the collision between the nanostructures due to the repetitive bending and the aggregation with the dye. In contrast, since the aligned zinc oxide nanostructure electrode may disperse the effect of stress in the electrode due to the bending even in the case of the repetitive bending, the aligned zinc oxide nanostructure electrode may form a layer able to stably transport electrons with no breakage, and thus, the aligned zinc oxide nanostructure electrode may continuously maintain high efficiency.

### Experimental Example 2

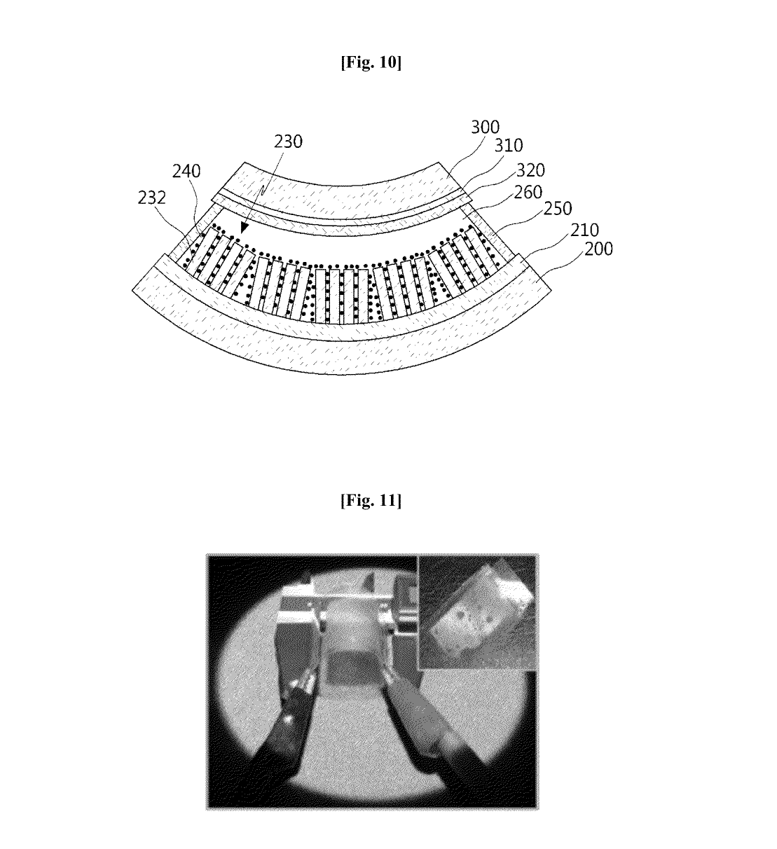

FIG. 10 is a sectional view illustrating a dye-sensitized solar cell prepared by using the method of preparing a dye-sensitized solar cell according to the embodiment of the present invention after bending, and FIG. 11 is an actual photograph showing an image of measuring the performance of the dye-sensitized solar cell prepared by using the method of preparing a dye-sensitized solar cell according to the embodiment of the present invention after bending.

Referring to FIGS. 10 and 11, FIG. 10 illustrates a section of a dye-sensitized solar cell in the case that the dye-sensitized solar cell prepared by the method of preparing a dye-sensitized solar cell according to the embodiment of the present invention described with reference to FIGS. 7 and 8 is bent. Since zinc oxide nanostructure electrodes 230 are patterned, the zinc oxide nanostructure electrodes 230 did not collide with the adjacent zinc oxide nanostructure electrodes 230 even in the case that the dye-sensitized solar cell is bent, and thus, the zinc oxide nanostructure electrodes 230 did not break. As a result, as illustrated in the following Table 1, in the case that bending of the dye-sensitized solar cell prepared by the method of preparing a dye-sensitized solar cell according to the embodiment of the present invention was repeated many times, the performance thereof may not be degraded.

At this time, Ru[dcbpy(TBA)₂]₂(NCS)₂ was used as the dye 232, 1-hexyl-2,3-dimethyl imidazolium iodide was used as the electrolyte 260, a PET substrate was used as the second substrate 300, a ITO layer was used as the transparent conductive layer 310, and a Pt layer was used as the counter electrode 320.

TABLE 1

| Number of | Voc | Jsc | FF | η |
|---|---|---|---|---|
| bending | (V) | (mA/cm²) | (%) | (%) |
| 1 | 0.56 | 9.85 | 52.5 | 2.91 |
| 10 | 0.55 | 9.86 | 51.89 | 2.79 |
| 50 | 0.55 | 9.54 | 52.36 | 2.75 |
| 100 | 0.55 | 9.11 | 52.92 | 2.64 |
| 300 | 0.56 | 9.32 | 53.30 | 2.79 |
| 500 | 0.55 | 8.85 | 52.23 | 2.56 |

That is, as illustrated in Table 1, since there were almost no changes in the measurements of open-circuit voltage (Voc (V)) formed between the transparent conductive layer 210 and the counter electrode 320 when light was incident in a state in which a circuit was opened, reverse (negative value) current density (Jsc (mA/cm²) generated when light was incident in a state in which a circuit was shorted, a fill factor (FF (%)), a value obtained by dividing the product of current density and a voltage value at a maximum power point (Vmp*Jmp) by the product of potential difference and current density, and a dye-sensitized solar cell efficiency (η (%)), a ratio of maximum power produced by the dye-sensitized solar cell to maximum electric energy that may be generated by the incident sunlight even after 500 times bending, it may be understood that there was almost no performance degradation due to the bending.

Therefore, the dye-sensitized solar cell prepared by the method of preparing a dye-sensitized solar cell according to the embodiment of the present invention was a flexible dye-sensitized solar cell and it may be understood that it was a stable dye-sensitized solar cell that almost maintained the characteristics thereof after the bending.

While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, the preferred embodiments should be considered in descriptive sense only and not for purposes of limitation.

1. A method of preparing a zinc oxide nanostructure electrode, the method comprising:
sequentially forming a superhydrophobic self-assembled layer and a zinc layer on a carrier substrate having a stamp pattern included therein;
disposing the zinc layer on the carrier to face a first substrate and performing a stamp method to form at least one zinc pattern on the first substrate;
oxidizing the zinc pattern to form zinc oxide seeds; and
growing at least one zinc oxide nanostructure from the zinc oxide seeds by using a hydrothermal synthesis method to form a zinc oxide nanostructure electrode composed of the at least one zinc oxide nanostructure.

2. The method of claim 1, wherein the first substrate comprises a transparent flexible substrate and a transparent conductive layer disposed on a surface of the flexible substrate, and the zinc pattern is disposed on the transparent conductive layer.

3. The method of claim 2, wherein the transparent flexible substrate is any one of an ultra-thin glass substrate, a polyethylene terephthalate (PET) substrate, a polycarbonate (PC) substrate, a polyether sulfone (PES) substrate, a polyimide (PI) substrate, a polynorbonene substrate, and a polyethylene naphthalate (PEN) substrate.

4. The method of claim 1, wherein the oxidizing of the zinc pattern to form zinc oxide seeds comprises oxidizing the zinc pattern by dipping the first substrate having the zinc pattern formed thereon in a polar solution as a hydroxide ion source to form the zinc oxide seeds.

5. The method of claim 4, wherein the polar solution as a hydroxide ion source comprises any one of NH₄OH, KOH, LiOH, and NaOH.

6. The method of claim 1, wherein the growing of the at least one zinc oxide nanostructure from the zinc oxide seeds by using a hydrothermal synthesis method to form a zinc oxide nanostructure electrode composed of the at least one zinc oxide nanostructure is performed by dipping the first substrate having the zinc oxide seeds formed thereon in a hydrothermal solution, and the hydrothermal solution comprises water, a zinc ion source supplying zinc ions by reacting with the water, and a hydroxide ion source supplying hydroxide ions by reacting with the water.

7. The method of claim 6, wherein the zinc ion source is any one of zinc acetate (Zn(O₂CCH₃)₂), zinc nitrate (Zn(NO₃)₂), zinc sulfate (ZnSO₄), and zinc chloride (ZnCl₂).

8. The method of claim 6, wherein the hydroxide ion source is hexamethylenetetramine.

9. A method of preparing a dye-sensitized solar cell, the method comprising:
sequentially forming a superhydrophobic self-assembled layer and a zinc layer on a carrier substrate having a stamp pattern included therein;
disposing the zinc layer on the carrier to face a first substrate and performing a stamp method to form at least one zinc pattern on the first substrate;
oxidizing the zinc pattern to form zinc oxide seeds;
growing at least one zinc oxide nanostructure from the zinc oxide seeds by using a hydrothermal synthesis method to form a zinc oxide nanostructure electrode composed of the at least one zinc oxide nanostructure;
adsorbing a dye on the zinc oxide nanostructure electrode; and
sealing by fastening the first substrate having the dye adsorbed thereon and a second substrate to fill an electrolyte therebetween.

10. The method of claim 9, wherein the second substrate further comprises a platinum (Pt) layer on a surface facing the first substrate.

11. The method of claim 10, wherein the second substrate comprises a transparent flexible substrate and a transparent conductive layer disposed on a surface of the flexible substrate, and the Pt layer is disposed on the transparent conductive layer.

12. The method of claim 10, wherein the second substrate is a conductive flexible substrate.

13. The method of claim 9, wherein the sealing by fastening the first substrate and the second substrate comprises sealing by fastening an edge of the first substrate and an edge of the second substrate with a fastening member, and the first substrate and the second substrate are spaced apart with a predetermined spacing and fastened.

14. A dye-sensitized solar cell comprising:
a first substrate; and
at least one patterned zinc oxide nanostructure electrode disposed on the first substrate and composed of at least one zinc oxide nanostructure.

15. The dye-sensitized solar cell of claim 14, further comprising:
a dye adsorbed on a surface of the zinc oxide nanostructure of the zinc oxide nanostructure electrode;
a second substrate facing the first substrate;
a fastening member fastening and sealing the first substrate and the second substrate; and
an electrolyte filled between the first substrate and the second substrate.

16. The dye-sensitized solar cell of claim 15, wherein the first substrate comprises a transparent flexible substrate and the second substrate comprises a flexible substrate.
